(19) United States
(12) Patent Application Publication
(10) Pub. No.: US 2026/0362599 A1
(43) Pub. Date: Nov. 12, 2026

(54) VARIABLE CIRCUIT BOARD AND BATTERY PACK INCLUDING THE VARIABLE CIRCUIT BOARD

(71) Applicant: SAMSUNG SDI CO., LTD., Yongin-si (KR)

(72) Inventors: CHANGSEONG KANG, Yongin-si (KR); JUNGWOO NOH, Yongin-si (KR)

(21) Appl. No.: 19/671,590

(22) Filed: May 8, 2026

(30) Foreign Application Priority Data
May 12, 2025 (KR) 10-2025-0061369

(51) Int. Cl. H05K 1/14; H01M 10/42; H01M 50/519

(52) U.S. Cl. CPC H05K 1/142; H01M 10/425; H01M 50/519; H01M 2010/4271; H05K 2201/09027

(57) ABSTRACT

A variable circuit board includes a first circuit board on which one or more electronic components are mounted and a second circuit board positioned at a first end of the first circuit board and electrically connected to the first circuit board. A cut-out region is formed at a second end of the first circuit board opposite to the first end at which the second circuit board is positioned.

### CROSS-REFERENCE TO RELATED APPLICATION

This application is based on and claims priority under 35 U.S.C. §119 to Korean Patent Application No. 10-2025-0061369, filed on May 12, 2025, in the Korean Intellectual Property Office, the disclosure of which is incorporated by reference herein in its entirety.

### BACKGROUND

### 1. Field

The present disclosure relates to a variable circuit board and a battery pack including the variable circuit board.

### 2. Description of the Related Art

A secondary battery is a type of battery that can be charged and discharged, unlike a primary battery that cannot be recharged. Low-capacity battery cells are used in small, portable-sized electronic devices such as smartphones, feature phones, laptop computers, digital cameras, and camcorders. High-capacity battery cells are widely used as power sources for driving motors and for energy storage in applications such as hybrid vehicles and electric vehicles. These battery cells include an electrode assembly comprising a positive electrode and a negative electrode, a case for accommodating the electrode assembly, and electrode terminals connected to the electrode assembly.

### SUMMARY

The present disclosure provides a variable circuit board whose length is adjustable to correspond to the size of a battery cell and a battery pack including the variable circuit board.

However, the technical problems to be solved by the present disclosure are not limited to the problems described above, and other solved problems not mentioned will be clearly understood by those skilled in the art from the disclosure described below.

An embodiment of the present disclosure provides a variable circuit board including a first circuit board on which one or more electronic components are mounted, and a second circuit board positioned at a first end of the first circuit board and electrically connected to the first circuit board, wherein a cut-out region is formed at a second end of the first circuit board opposite to the first end at which the second circuit board is positioned.

In some embodiments, an edge of the second end is curbed.

In some embodiments, a radius of curvature of the edge may be 1.5R to 2.5R.

In some embodiments, the cut-out region may include a plurality of cut-out portions.

In some embodiments, each of the cut-out portions may have a shape corresponding to the shape of an edge of the second end of the first circuit board.

In some embodiments, each of the cut-out portion includes a plurality of holes, and the holes may be arranged in a shape corresponding to a shape of the edge of the second end of the first circuit board.

In some embodiments, the distance between holes of one of the cut out portions to corresponding holes of an adjacent one of the cut out portions may be 0.1 mm to 0.3 mm.

In some embodiments, the length of the cut -out region is configured to be reduced when the circuit board is cut along one of the cut-out portions.

In some embodiments, the cut-out region may be configured to be separated by a jig having a shape corresponding to the shape of a region separated when an outermost cut-out portion among the cut-out portions is cut.

In some embodiments, the width of the first circuit board intersecting the longitudinal direction of the first circuit board may be 3.2 mm to 3.5 mm.

In some embodiments, the first circuit board and the second circuit board may be electrically connected by solder.

Another embodiment of the present disclosure provides a battery pack including a battery cell, a first circuit board electrically connected to the battery cell, and a second circuit board positioned at a first end of the first circuit board, the second circuit board being electrically connected to the first circuit board, a second end of the second circuit board includes an external connection terminal, wherein the first circuit board has a cut-out region formed at a second end opposite to the first end at which the second circuit board is positioned.

In some embodiments, an edge of the second end is curved.

In some embodiments, a radius of curvature of the edge may be of 1.5R to 2.5R.

In some embodiments, the cut-out region may include a plurality of cut-out portions.

In some embodiments, each of the cut-out portions may have a shape corresponding to the shape of an edge of the second end of the first circuit board.

In some embodiments, each of the cut-out portions may include a plurality of holes, and the holes may be arranged in a shape corresponding to the shape of the edge of the second end of the first circuit board.

In some embodiments, the distance between holes of one of the cut out portions to corresponding holes of an adjacent one of the cut-out portions is 0.1 mm to 0.3 mm.

In some embodiments, the length of the cut-out region may decrease when the circuit board is cut along one of the cut-out portions.

In some embodiments, the width of the first circuit board intersecting the longitudinal direction of the first circuit board may be 3.2 mm to 3.5 mm.

### BRIEF DESCRIPTION OF THE DRAWINGS

The drawings illustrate preferred embodiments of the present disclosure and, together with the detailed description of the disclosure set forth below, serve to further facilitate an understanding of the technical spirit of the present disclosure. But the present disclosure is not limited to the embodiments depicted in the drawings.

FIG. 1 is an exploded perspective view of a battery pack according to an embodiment of the present disclosure;

FIG. 2 is a plan view of a variable circuit board according to an embodiment of the present disclosure;

FIG. 3 is a view of region A of FIG. 2;

FIG. 4 is an enlarged view of region A of FIG. 2;

FIG. 5 is a cross-sectional view taken along line I-l' of FIG. 4;

FIG. 6 is a view of another embodiment of thef region A of FIG. 2;

FIG. 7 is a cross-sectional view taken along line II-II' of FIG. 6.

FIGS. 8A and FIG. 8B are views of length adjustment of the variable circuit board of FIG. 2.

### DETAILED DESCRIPTION

Hereinafter, preferred embodiments of the present disclosure will be described in detail with reference to the attached drawings. It should be noted that terms or words used in this specification and the claims should not be interpreted as limited to their usual or dictionary meanings. Rather, they should be interpreted based on the principle that the inventor is entitled to define the terms appropriately to best explain the disclosure, and should be construed in accordance with the technical spirit of the present disclosure. Accordingly, the embodiments described in this specification and the configurations illustrated in the drawings are only some of the most preferred embodiments of the present disclosure and do not represent all of the technical spirit of the present disclosure, and it should be understood that there may be various equivalents and modifications that may replace them at the time of filing this application.

In addition, as used in this specification, the terms “comprise” and/or “include,” as well as variations thereof such as “comprising” and/or “including,” specify the presence of stated features, numbers, steps, operations, elements, components and/or groups thereof, but do not preclude the presence or addition of one or more other features, numbers, operations, elements, components and/or groups thereof.

To aid understanding of the disclosure, the attached drawings are not drawn to scale and the dimensions of some components may be exaggerated. In addition, the same reference numbers may be assigned to the same components in different embodiments.

Although the terms such as first, second, etc. are used to describe various components, these components are not limited by these terms. These terms are merely used to distinguish one component from another, and unless otherwise stated, it should be understood that a first component may be the same as or interchangeable with a second component.

Throughout the specification, unless otherwise specified, each element may be singular or plural.

The expression that a certain structure is positioned “on (or under)” a component, or “above (or below)” the component, may mean not only that the structure is positioned in contact with the upper (or lower) surface of the component, but also that one or more other structures may be interposed between the component and the structure positioned above (or below) it.

In case that it is described that a component is “connected,” “coupled,” or “joined” to another component, it should be understood that the components may be directly connected or joined to each other, or one or more other components may also be “interposed” between the components, such that the components may be “connected,” “coupled,” or “joined” to each other through other components. Furthermore, in case that we say that a part is electrically coupled to another part, this includes not only the case where they are directly connected, but also the case where they are connected with another element in between.

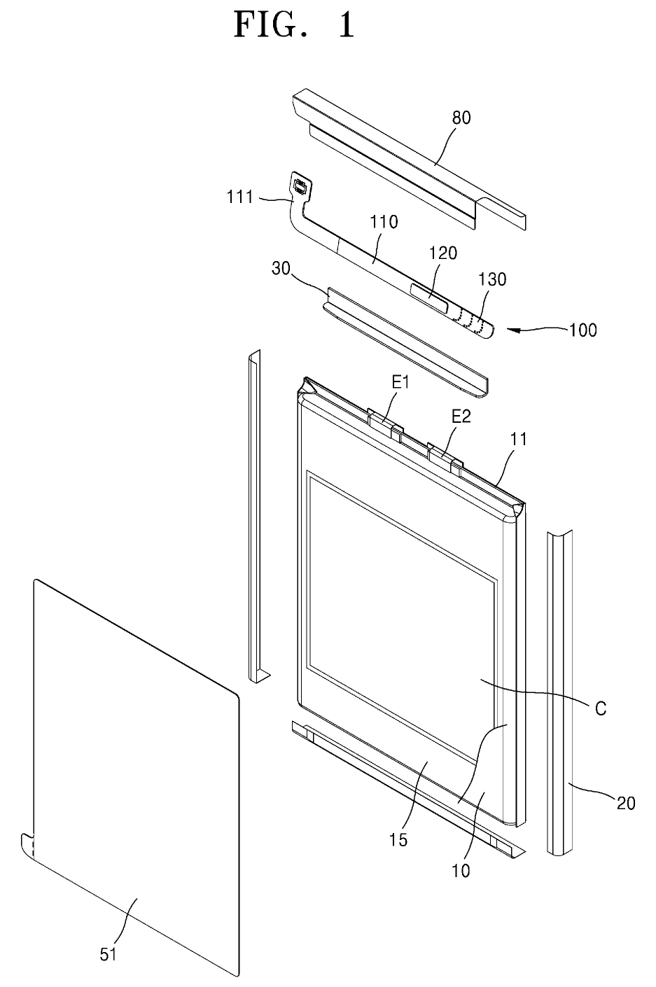

FIG. 1 is an exploded perspective of a battery pack according to an embodiment of the present disclosure.

Referring to FIG. 1, an insulating tape 20 may be attached along the edge portion of a battery cell C. An insulating adhesive tape 30 may be interposed between a terrace portion 11 of the battery cell C and a variable circuit board 100 to provide an insulating bond between the first circuit board 110 and the second circuit board 111. In some embodiments, an insulating member 80 may be attached on the variable circuit board 100 to insulate and protect the first circuit board 110 and the second circuit board 111 from the surrounding environment. The battery pack may further include a label sheet 51 attached to the battery cell C. The label sheet 51 insulates and protects the battery cell C, and the label sheet 51 provides a display area for showing product information such as a model name or manufacturer of the battery cell C.

The battery cell C may include an electrode assembly 10. An exterior member 15 may seal an electrolyte (not shown) together with the electrode assembly 10. The exterior member 15 includes a terrace portion 11 from which a first electrode E1 and a second electrode E2, which are electrically connected to the electrode assembly 10, extend. As will be described below, the variable circuit board 100 electrically connected to the first electrode E1 and the second electrode E2 may be positioned on the terrace portion 11.

The electrode assembly 10 may be wound by interposing a separator, which is an insulating member, between the positive electrode and the negative electrode. The positive electrode and the negative electrode are wound with an insulating separator interposed therebetween. However, the present disclosure is not limited to such a configuration. In other embodiments, the electrode assembly 10 may be, for example, a stacked structure in which a plurality of sheets of positive and negative electrodes are alternately stacked with separators interposed between the positive and negative electrodes.

The first electrode E1 or the second electrode E2 may be a positive electrode or a negative electrode. The positive and the negative electrodes may each include a coated portion where an active material is applied to a current collector formed of a thin metal foil and a non-coated portion where the active material is not provided.

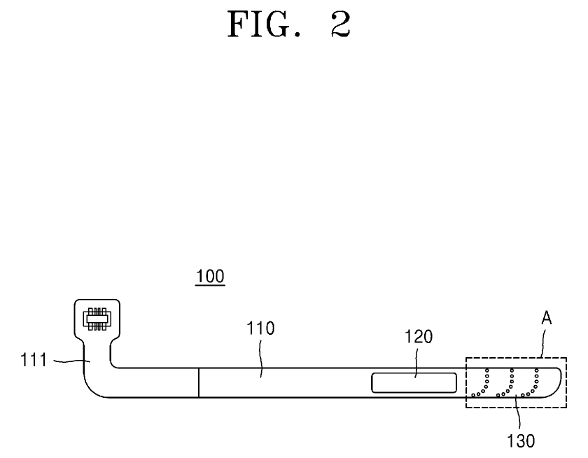

FIG. 2 is a plan view of a variable circuit board according to an embodiment of the present disclosure.

Referring to FIG. 2, a variable circuit board 100 according to an embodiment of the present disclosure may include a first circuit board 110 and a second circuit board 111 on which external connection terminals are positioned. The first circuit board 110 may have electronic components 120 and a cut-out region 130 positioned thereon.

The first circuit board 110 may be connected to the first electrode E1 and the second electrode E2 of the battery cell. For example, the first circuit board 110 may be electrically connected to the battery cell C by being connected to the tabs of the first electrode E1 and the second electrode E2 of the battery cell. As such, charging and discharging currents of the battery cell C may flow through the first circuit board 110 and may be delivered to external connection terminals of the second circuit board 111 that is connected in parallel to the first circuit board 110.

As the charging and discharging currents of the battery cell C are delivered to the external connection terminal of the second circuit board 111, which is connected in parallel on the first circuit board 110 via the first circuit board 110, the variable circuit board 100 may monitor the charging and discharging voltage, charging and discharging current, and/or temperature of the battery cell. The variable circuit board can thereby protect the battery cell from overcharging and overdischarging. The external connection terminal may be connected, for example, to an external electronic device to charge or discharge the battery cells. That is, the variable circuit board 100 may be a protection circuit module that protects the battery cell C from overcharging and overdischarging.

The second circuit board 111 connected to the first circuit board 110 may have one end electrically connected to the first circuit board 110 by, for example, soldering and an external connection terminal may be positioned at another end of the second circuit board 111 to be electrically connected to an external device.

For such protective operations to prevent overcharging, overdischarging and/or overcurrent of the battery cell C, at least one electronic component 120 may be mounted on the first circuit board 110 of the variable circuit board 100. The electronic component 120 may be, for example, a plurality of positive temperature coefficient (PTC) elements.

Unlike the second circuit board 111, the first circuit board 110 may be formed as a relatively lightweight and rigid circuit board. While forming a charging and discharging path between the battery cell C and the second circuit board 111, a plurality of electronic elements 120 may be positioned on the first circuit board 110 to control the charging and discharging operations of the battery cell C in response to abnormal conditions such as overheating, overcharging, or overdischarging of the battery cell C.

In some examples, the first circuit board 110 may function as a battery management system (BMS) configured to monitor status information such as temperature, voltage, and current of the battery cell C, detect abnormal conditions, and take protective measures such as stopping charging and discharging operations. Thus, as discussed above, the first circuit board 110 may be formed as a relatively lightweight and rigid circuit board. However, in some embodiments of the present disclosure, the first circuit board 110, like the second circuit board 111, may be a flexible film type.

The second circuit board 111 may extend in parallel with the first circuit board 110 along a longitudinal direction of the first circuit board 110. The electrical connection between the first circuit board 110 and the second circuit board 111 may be made through a bonding material, such as solder, formed on each of the first circuit board 110 and the second circuit board 111.

The first circuit board 110 may include a first end and a second end opposite to the first end, with the first end being connected to the second circuit board 111 and a cut-out region 130 being formed at the second end. The cut-out region 130 at the second end may be an empty space on which no electronic component 120 is mounted. By cutting out this region, the length of the variable circuit board 100 may be adjusted to correspond to battery cells C manufactured in various sizes. This is advantageous because when a circuit board does not correspond to the size of the battery cell C, the circuit board may press against and thereby damage to the battery cell C.

Early market entry can be important when developing new models of battery packs. However, for protection circuit modules manufactured separately from the development of the battery pack, a new protection circuit design may be required to fit a new battery pack model. Such new designs take a lot of time, making it difficult for new battery pack models to quickly enter the market.

However, the variable circuit board 100 according to embodiments of the present disclosure may meet the specifications of a newly developed battery pack model by including a cut-out region 130, thereby reducing unnecessary circuit board design time.

Although the battery cell C may be manufactured in various sizes, the spacing between the first electrode E1 and the second electrode E2 may be constantly maintained. Accordingly, even if the length of the variable circuit board 100 is adjusted to correspond to the size of the battery cell C manufactured in various sizes, the variable circuit board 100 may be electrically connected to the first electrode E1 and the second electrode E2 of the battery cell C.

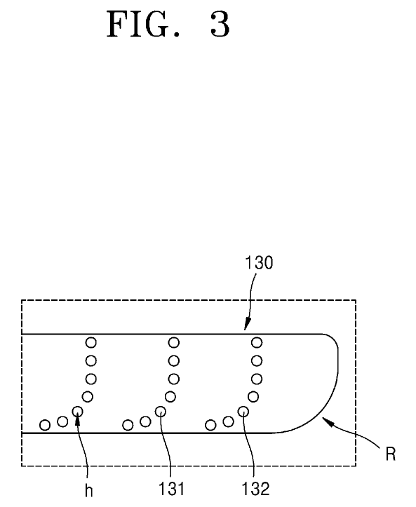

FIG. 3 is an enlarged view of region A of FIG. 1.

Referring to FIG. 3, the cut-out region 130 may include a plurality of cut-out portions 131 and 132. The cut-out portions 131 and 132 may be arranged in the cut-out region 130 and be the same shape, and one cut-out portion 131 may be configured such that a plurality of holes h are arranged side by side in a linear form at the second end of the first circuit board 110. In a specific embodiment, the plurality of holes h may be arranged side by side in a linear form in the widthwise direction of the first circuit board 110, which intersects the longitudinal direction of the first circuit board 110, so as to correspond to the size of the width of the first circuit board 110. The cut-out portions 131 and 132 may be cut out and separated from the cut-out region 130 of the first circuit board 110, and the length of the variable circuit board 100 may be adjusted by cutting out one or more of the cut-out portions, beginning with the second cut-out portion 132 located at the outermost edge of the second end of the first circuit board 110.

In some embodiments, the distance between the first cut-out portion 131 and the adjacent second cut-out portion 132 may be from 1 mm to 2 mm. Each time the cut-out portion 132 at the other end of the first circuit board 110 is cut, the length of the first circuit board 110 may be reduced by the distance between the adjacent first cut-out portions 131 and second cut-out portions 132. That is, each time the cut-out portion 132 is cut, the length of the first circuit board 110 may be reduced by 1 mm to 2 mm, which may correspond to the interval needed to adjust the length of the variable circuit board 100 to correspond to various sizes of battery cells C.

An end of the first circuit board 110 may be formed so that a region facing the battery cell has a certain curvature when connected to the battery cell. If the first circuit board does not have such a curvature, the battery cell may be damaged by being pressed by the end of the first circuit board 110.

In specific examples, the radius of curvature (e.g., The radius of curvature(R) is a measure of how sharply a curve or surface bends at a specific point, representing the radius of a circular arc that best approximates the curve at that point. It is the inverse of the curvature, with a smaller radius indicating a more pronounced curve and a larger radius signifying a gentler curve) of the first circuit board 110 may be in the range of 1.5R to 2.5R. In case where the curvature is less than 1.5R, the edge of the other end of the first circuit board 110 may be sharp and may thereby damage the battery cell when the first circuit board is pressed against the battery cell. When the curvature exceeds 2.5R, processing of the end of the first circuit board 110 may be difficult.

The cut-out portion 131, in which a plurality of holes h are arranged side by side in a linear form at the other end of the first circuit board 110 may have a shape corresponding to the shape of the end of the first circuit board 110. For example, the cut-out portion 131 may be formed with the same R value as the curvature formed at the other end of the first circuit board 110, and the distance between adjacent holes h may be from 0.1 mm to 0.3 mm. When the distance between the holes h is less than 0.1 mm, the cut-out portions 131 and 132 may be separated too easily. When the distance between the holes h exceeds 0.3 mm, separation of the cut-out portions 131 and 132 may be difficult, making it difficult to smoothly separate the cut-out portions 131 and 132.

In some embodiments, the width in the direction intersecting the longitudinal direction of the first circuit board 110 may be 3.2 mm to 3.5 mm. When the width of the first circuit board 110 is less than 3.2 mm, the rigidity of the first circuit board 110 may be insufficient and the first circuit board 110 may be easily damaged. When the width of the first circuit board 110 exceeds 3.5 mm, the first circuit board 110 may overlap with the terrace portion 11 of the battery cell described below, which may cause damage to the battery cell C.

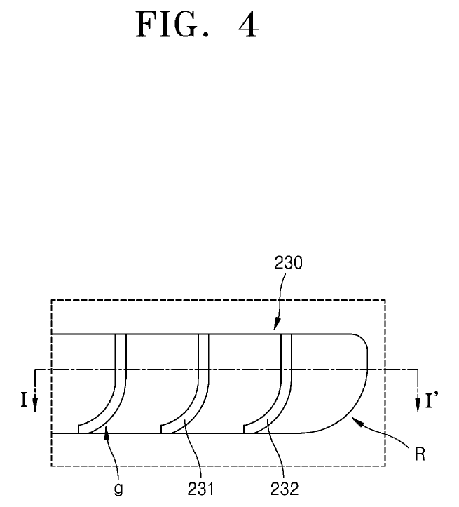

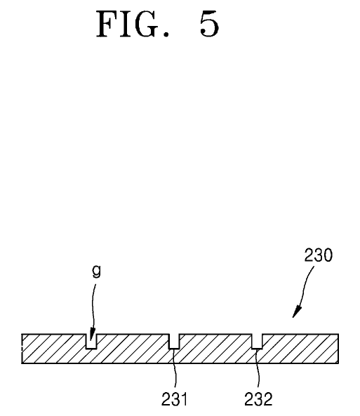

FIG. 4 is a schematic drawing showing the region A of FIG. 2 enlarged, and FIG. 5 is a cross-sectional view taken along line I-I' of FIG. 4.

Referring to FIGS. 4 and 5, the cut-out region 230 may include a plurality of cut-out portions 231 and 232. The plurality of cut-out portions 231 and 232 may be the same shapes and positioned in the cut-out region 230. The first cut-out portion 231 and the second cut-out portion 232 may be formed at the second end of the first circuit board 110. A groove g having a defined depth in the thickness direction of the first circuit board 110 may be formed in a surface of the first circuit board 110. In the depicted configuration, the length of the groove g may correspond to the width of the first circuit board 110 in a direction intersecting the longitudinal direction of the first circuit board 110. Here, the first cut-out portion 231 and the second cut-out portion 232 may be cut out and separated from the cut-out region 230 of the first circuit board 110, and the length of the variable circuit board 100 may be adjusted by cutting out one or more of the cut-out portions starting from the second cut-out portion 232 located at the outermost edge of the other end of the first circuit board 110.

In specific embodiments, the distance between the first cut-out portion 231 and the adjacent second cut-out portions 232 may be from 1 mm to 2 mm. Each time one of the first cut-out portion 231 and the second cut-out portions 232 at the end of the first circuit board 110 is cut, the length of the first circuit board 110 may be reduced by the distance between the first cut-out portion 231 and the second cut-out portions 232. That is, each time one of the first cut-out portion 231 and the second cut-out portions 232 is cut, the length of the first circuit board 110 may be reduced by 1 mm to 2 mm, which may correspond to the interval needed to adjust the length of the variable circuit board 100 to correspond to various sizes of battery cells.

An end of the first circuit board 110 may be formed so that a region facing the battery cell has a certain curvature when connected to the battery cell. If the first circuit board does not have such a curvature, the battery cell may be damaged by the end of the first circuit board 110.

In specific examples, the radius of curvature of the first circuit board 110 may be from 1.5R to 2.5R. In case where the curvature is less than 1.5R, the edge of the other end of the first circuit board 110 may be sharp and may thereby damage the battery cell. When the curvature is greater than 2.5R, processing of the end of the first circuit board 110 may be difficult.

The first cut-out portion 231 and the second cut-out portion 232 may be arranged in parallel to each other at the second end of the first circuit board 110. And the first and second cut-out portions 231 and 232 include grooves g corresponding to the width direction of the first circuit board 110. More specifically, the first cut-out portion 231 and the second cut-out portion 232 may have a shape corresponding to the second end of the first circuit board 110 and may have a a radius of curvature R corresponding to the The radius of curvature of the second end of the first circuit board 110. Each of the grooves g may have a depth that is recessed in the thickness direction of the first circuit board 110. A ratio of the depths relative to the thickness of the first circuit board 110 may be 3:1 to 3:2. When the depths of the grooves g relative to the thickness of the first circuit board 110 is less than 3:1, it may be difficult to cut the cut-out portions 231 and 232. When the depths of the grooves g relative to the thickness of the first circuit board 110 exceeds 3:2, the thickness of the first cut-out portion 231 and the second cut-out portion 232 may become too small, and the first circuit board may be too easily separated at the first cut-out portion 231 and/or the second cut-out portion 232.

In some embodiments, the width of the first circuit board 110 in a direction intersecting the longitudinal direction thereof may be in a range of 3.2 mm to 3.5 mm. When the width of the first circuit board 110 is less than 3.2 mm, the rigidity of the first circuit board 110 may be insufficient and the first circuit board 110 may be easily damaged. When the width of the first circuit board 110 exceeds 3.5 mm, the first circuit board 110 may overlap with a terrace portion 11 of a battery cell, which may cause damage to the battery cell C.

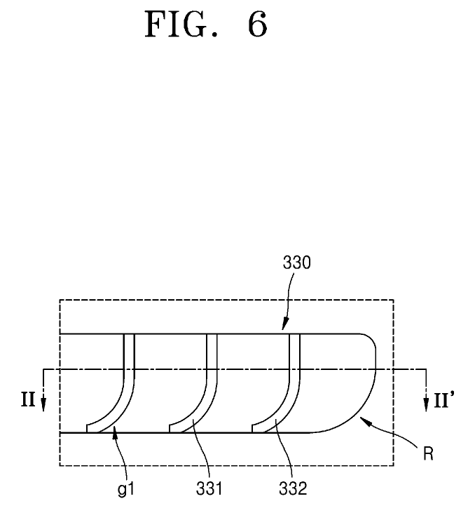

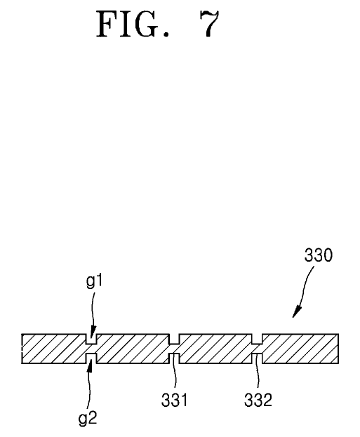

FIG. 6 is an enlarged view of the region A of FIG. 2 according to another embodiment, and FIG. 7 is a cross-sectional view taken along line II-II' of FIG. 6.

Referring to FIGS. 6 and 7, the cut-out region 330 may include a plurality of cut-out portions 331 and 332. Each of the cut-out portions 331 and 332 may be the same shape in the cut-out region 330. The cut-out portions 331 and 332 may each include a first groove g1and a second groove g2 at the second end of the first circuit board 110, with the first groove g1 and the second groove g2 being formed in surfaces on opposite sides of the first circuit board 110. Each of the grooves g1 and g2 may have a defined depth recessed in the thickness direction of the first circuit board 110 such that the first groove g1 and the second groove g2correspond to each other. In this regard, the length of each of the first groove g1 and the second groove g2may correspond to the length in the width direction of the first circuit board 110, which intersects the longitudinal direction of the first circuit board 110. The length of the variable circuit board 110 may be adjusted by cutting the cut-out portions 331 and 332 starting from the second cut-out portion 332 located at the outermost edge of the second end of the first circuit board 110 and optionally cutting the first cut-out portion 331 to make the variable circuit board 110 even shorter.

In a specific example, the distance between the first cut-out portion 331 and the adjacent second cut-out portion 332 may be 1 mm to 2 mm. Each time the variable circuit board 100 is cut along one of the cut-out portions 331 and 332, the length of the first circuit board 110 may be reduced by an amount corresponding to the distance between the first cut-out portion 331 and the second cut-out portion 332. That is, each time the first cut-out portion 331 and the second cut-out portion 332 is cut, the length of the first circuit board 110 may be reduced by 1 mm to 2 mm, which may correspond to the interval needed to adjust the length of the variable circuit board 100 to correspond to various sizes of battery cells C.

In some embodiments, the second end of the first circuit board 110 may be formed so that a region in the direction facing the battery cell C has a curvature when connected to the battery cell. In this case, if the first circuit board 110 does not have such a curvature the battery cell C may be damaged when it is pressed by the first circuit board 110.

In specific examples, the curvature of the first circuit board 110 may range from 1.5R to 2.5R. When the curvature is less than 1.5R, the edge of the second end of the first circuit board 110 may be sharp, which may cause damage to the battery cell is pressed. When the curvature exceeds 2.5R, processing of the second end of the first circuit board 110 may be difficult.

The first cut-out portion 331 and the second cut-out portion 332 may be positioned at the second end of the first circuit board 110, and may each include a first groove g1 and a second groove g2 formed at corresponding positions in surfaces on opposite sides of the first circuit board 110 such that the first groove g1and the second groove g2are positioned corresponding to the length in the width direction of the first circuit board 110. The first cut-out portion 331 and the second cut-out portion 332 may each include a shape corresponding to the shape of the second end of the first circuit board 110 and may have a curvature having a radius R equal to that of the curvature formed at the second end of the first circuit board 110. The sum of the depths of the first groove g1 and the second groove g2, which are each recessed in the thickness direction of the first circuit board 110, may be at a ratio of 3:1 to 3:2 relative to the thickness of the first circuit board 110. When the sum of the groove depths is less than a 3:1 ratio with respect to the thickness of the first circuit board 110, it may difficult to cut the cut-out portions 331 and 332. When the sum of the groove depths exceeds a 3:2 ratio with respect to the thickness of the first circuit board 110, the remaining thickness of the first circuit board 110 between the grooves g1and g2may be too small, leading to potentially causing unintended separation at the cut-out portions 331 and 332.

The width of the first circuit board 110 in the direction intersecting its longitudinal direction may be in the range of 3.2 mm to 3.5 mm. When the width of the first circuit board 110 is less than 3.2 mm, the rigidity of the first circuit board 110 may be insufficient, potentially leading to its damage or breakage. When the width of the first circuit board 110 exceeds 3.5 mm, the first circuit board 110 may overlap with a terrace portion 11 of the battery cell, which may cause damage to the battery cell.

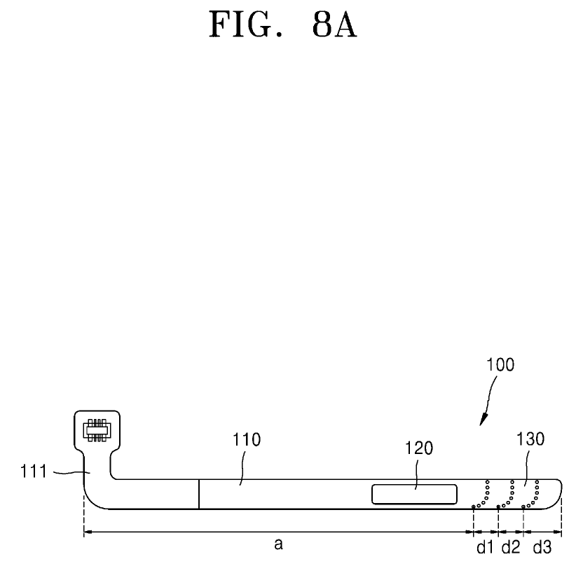

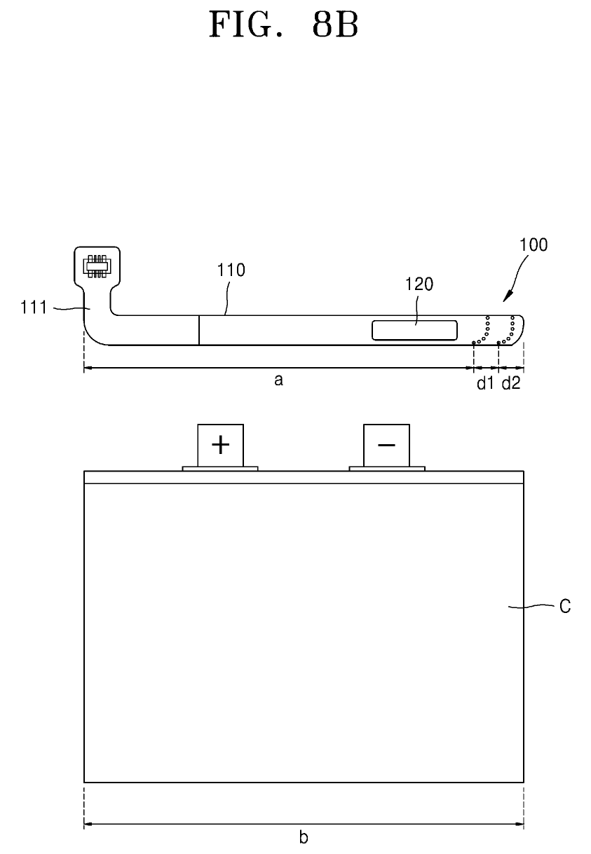

FIGS. 8A and 8B illustrate an embodiment of length adjustment of the variable circuit board of FIG. 1.

Referring to FIG. 8A, the variable circuit board 100 may have a length of a+d1+d2+d3. In this case, the length of the cut-out region 130 may be d1+d2+d3.

Referring to FIG. 8B, when the outermost cut-out portion of the variable circuit board 100 of FIG. 8A is cut off, the variable circuit board 100 may have a length of a+d1+d2. That is, when a region corresponding to d3 among the cut-out regions 130 is cut off and separated, and the length of the cut-out region 130 may become d1+d2, as depicted in FIG. 8B. By cutting out a portion corresponding to d3 among the cut-out regions 130 of the variable circuit board 100, the length of the variable circuit board 100 may be made to correspond to the size b of the battery cell c.

In another embodiment, the cut-out region 130 may be separated by a jig having a shape corresponding to the shape of a cut-out region 130 that is separated when one or more of the plurality of cut-out portions is cut and separated. For example, a single cut-out region 130 separated by the cut-out portions, and specifically, the cut-out region 130 corresponding to d3, may be cut by means of a jig having the same shape as the region corresponding to d3. By cutting the cut-out region using a jig having the same shape as the cut-out region 130 corresponding to d3, the cut-out region may be smoothly separated.

the length of the variable circuit board 100 may be adjusted to correspond to the various sizes of battery cells by adjusting the length of the cut-out region 130 by cutting the cut-out portion. Thus, the variable circuit board 100 may be applied to battery cells of various sizes by adjusting the length to correspond to the various sizes of battery cells.

According to embodiments of the present disclosure, a variable circuit board may include a cut-out region, whereby its length may be adjusted to accommodate battery cells of various sizes. As such, by enabling length adjustment in response to different battery cell sizes, a single circuit board may be applied to battery cells of multiple dimensions.

While the present disclosure has been described with reference to specific embodiments and drawings, it is not limited thereto. Various modifications, alterations, and equivalents may be made by those skilled in the art without departing from the spirit and scope of the disclosure.

What is claimed is:

1. A variable circuit board comprising:
a first circuit board on which one or more electronic components are mounted; and
a second circuit board positioned at a first end of the first circuit board and electrically connected to the first circuit board,
wherein a cut-out region is formed at a second end of the first circuit board opposite to the first end at which the second circuit board is positioned.

2. The variable circuit board of claim 1, wherein an edge of the second end is curved.

3. The variable circuit board of claim 2, wherein a radius of curvature of the edge is 1.5R to 2.5R.

4. The variable circuit board of claim 2, wherein the cut-out region includes a plurality of cut-out portions.

5. The variable circuit board of claim 4, wherein each of the cut-out portions has a shape corresponding to a shape of an edge of the second end of the first circuit board.

6. The variable circuit board of claim 5, wherein each of the cut-out portions includes a plurality of holes, and
wherein the holes are arranged in a shape corresponding to a shape of the edge of the second end of the first circuit board.

7. The variable circuit board of claim 6, wherein a distance between adjacent holes among the plurality of holes is in a range of 0.1 mm to 0.3 mm.

8. The variable circuit board of claim 4, wherein a length of the cut-out region decreases when the circuit board is cut along one of the cut-out portions.

9. The variable circuit board of claim 4, wherein the cut-out region is configured to be separated by a jig having a shape corresponding to the shape of a region separated when an outermost one of the cut-out portions is cut.

10. The variable circuit board of claim 1, wherein a width of the first circuit board intersecting a longitudinal direction of the first circuit board is 3.2 mm to 3.5 mm.

11. The variable circuit board of claim 1, wherein the first circuit board and the second circuit board are electrically connected by solder.

12. A battery pack comprising:
a battery cell;
a first circuit board electrically connected to the battery cell; and
a second circuit board positioned at to a first end of the first circuit board, the second circuit board being electrically connected to the first circuit board at a first end of the second circuit board is electrically, and a second end of the second circuit board including an external connection terminal, and
wherein a cut-out region is formed at a second end of the first circuit board that is opposite to the first end at which the second circuit board is positioned.

13. The battery pack of claim 12, wherein an edge of the second end is curved

14. The battery pack of claim 13, wherein a radius of curvature of the edge is 1.5R to 2.5R.

15. The battery pack of claim 13, wherein the cut-out region comprises a plurality of cut-out portions.

16. The battery pack of claim 15, wherein each of the cut-out portions has a shape corresponding to a shape of an edge of the second end of the first circuit board.

17. The battery pack of claim 16, wherein each of the cut-out portions includes a plurality of holes, and
wherein the holes are arranged in a shape corresponding to a shape of the edge of the second end of the first circuit board.

18. The battery pack of claim 17, wherein a spacing between adjacent holes of the plurality of holes is in a range of 0.1 mm to 0.3 mm.

19. The battery pack of claim 15, wherein a length of the cut-out region decreases when the circuit board is cut along one of the cut-out portions.

20. The battery pack of claim 12, wherein a width of the first circuit board intersecting a longitudinal direction of the first circuit board is 3.2 mm to 3.5 mm.
